(19) United States
(12) Patent Application Publication
(10) Pub. No.: US 2013/0100614 A1
(43) Pub. Date: Apr. 25, 2013

(54) ELECTRONIC DEVICE USING FASTENER FOR FIXING

(71) Applicants: Yi-Fei Yu, New Taipei City (TW); Yuan-Heng Huang, Taichung City (TW)

(72) Inventors: Yi-Fei Yu, New Taipei City (TW); Yuan-Heng Huang, Taichung City (TW)

(73) Assignee: SERCOMM CORPORATION, Tapei (TW)

(21) Appl. No.: 13/588,628

(22) Filed: Aug. 17, 2012

(30) Foreign Application Priority Data
Oct. 19, 2011 (CN) 201120401229.8

(51) Int. Cl. H05K 7/20

(52) U.S. Cl. 361/719

(57) ABSTRACT

An electronic device includes a circuit board, a communication chip, a ceramic heat sink and an elastic fastener. The circuit board has first and second fixing members. The communication chip is disposed on the circuit board. The ceramic heat sink disposed on the communication chip has first and second lateral sides. The elastic fastener includes a first extension portion, a second extension portion and a clamping portion. The first extension portion extending to the first fixing member from the first lateral side is engaged with the first fixing member to generate a first fastening force. The second extension portion extending to the second fixing member from the second lateral side is engaged with the second fixing member to generate a second fastening force. The clamping portion applies a force on the ceramic heat sink to tightly press the ceramic heat sink on the communication chip.

This application claims the benefit of People's Republic of China application Serial No. 201120401229.8, filed Oct. 19, 2011, the subject matter of which is incorporated herein by reference.

### BACKGROUND OF THE INVENTION

1. Field of the Invention

The invention relates in general to an electronic device, and more particularly to an electronic device using a fastener for fixing.

2. Description of the Related Art

For the heat generated by the chip during high speed computation to be quickly dissipated, the chip is normally equipped with heat sink plus the assistance of a fan. Normally, the heat sink is directly bonded on the chip for absorbing the heat generated by the chip via the contact surface between the heat sink and the chip.

However, the design of bonding the heat sink to the chip cannot assure that the heat sink and the chip are tightly bonded over the time. One of the reasons is that the heat generated by the chip may cause the colloid to change and make the heat sink unable to be tightly bonded with the chip or even come off the chip. If the chip and the heat sink are not tightly bonded, the heat generated by the chip will not be completely conducted and absorbed via the heat sink. The computation speed of the chip will be affected and the chip may even be damaged if the heat generated by the chip cannot be dissipated quickly.

### SUMMARY OF THE INVENTION

The invention is directed to an electronic device using a fastener for fixing. The fastener increases the fastening force, and improves the dissipation efficiency.

According to a first aspect of the present invention, an electronic device using a fastener for fixing is provided. The electronic device includes a circuit board, a communication chip, a ceramic heat sink and an elastic fastener. The circuit board has a first fixing member and a second fixing member disposed thereon. The communication chip is disposed on the circuit board. The ceramic heat sink is disposed on the communication chip, and has a first lateral side and a second lateral side which are parallel and opposite to each other. The elastic fastener comprises a first extension portion, a second extension portion and a clamping portion. The first extension portion extends to the first fixing member along a first direction from the first lateral side, and is engaged with the first fixing member to generate a first fastening force. The second extension portion extends to the second fixing member along a second direction from the second lateral side, and is engaged with the second fixing member to generate a second fastening force. The clamping portion is connected between the first extension portion and the second extension portion, and contacts and applies a force on the ceramic heat sink to tightly press the ceramic heat sink on the communication chip.

The above and other aspects of the invention will become better understood with regard to the following detailed description of the preferred but non-limiting embodiments. The following description is made with reference to the accompanying drawings.

### BRIEF DESCRIPTION OF THE DRAWINGS

FIG. 1A shows a decomposition diagram of an electronic device using a fastener for fixing according to an embodiment of the invention; and

FIG. 1B shows an assembly diagram of the electronic device using the fastener for fixing of FIG. 1A.

### DETAILED DESCRIPTION OF THE INVENTION

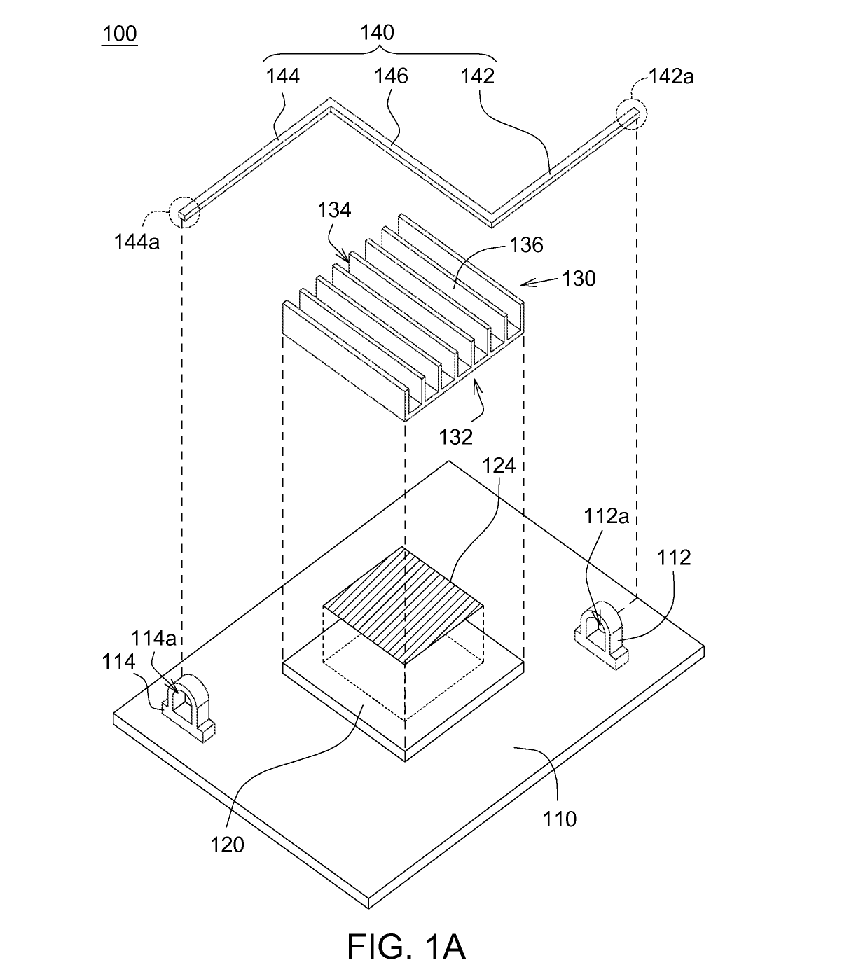

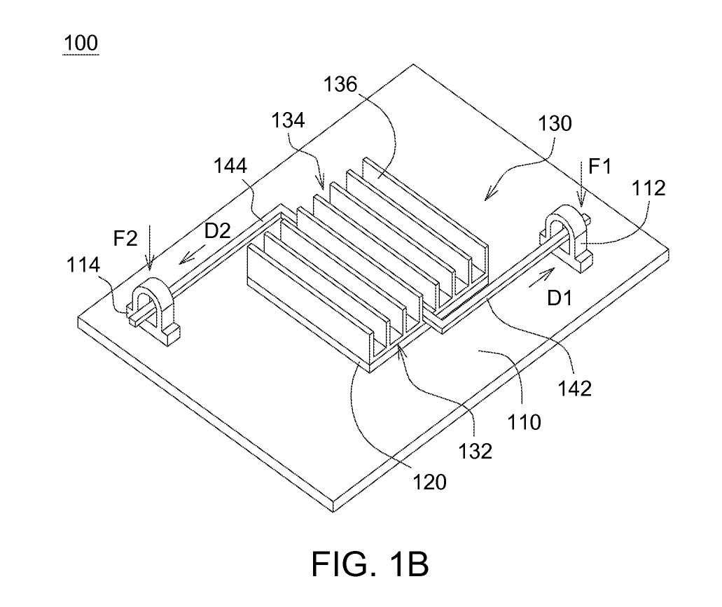

Referring to FIG. 1A and FIG. 1B. FIG. 1A shows a decomposition diagram of an electronic device using a fastener for fixing according to an embodiment of the invention. FIG. 1B shows an assembly diagram of the electronic device using the fastener for fixing of FIG. 1A.

As indicated in FIG. 1A and FIG. 1B, the electronic device 100 using a fastener for fixing includes a circuit board 110, a communication chip 120, a ceramic heat sink 130 and an elastic fastener 140. The circuit board 110 has a first fixing member 112 and a second fixing member 114 disposed thereon. The communication chip 120 is disposed on the circuit board 110. The ceramic heat sink 130 is disposed on the communication chip 120, and has a first lateral side 132 and a second lateral side 134 which are parallel and opposite to each other.

The ceramic heat sink 130 has the qualities of rigid hardness, anti-electrostatic and lightweight. The ceramic heat sink 130 can be disposed on the communication chip 120 to avoid electromagnetic interference. In addition, the ceramic material does not accumulate heat, has a porous structure, and outdoes the aluminum heat sink in heat dissipation. The ceramic heat sink 130 may be made from a porous material such as silicon carbide. Furthermore, the ceramic heat sink 130 has 30% more pores per unit surface area than metal heat sink, hence having larger air contacting area and dissipating more heat.

In the present embodiment, the ceramic heat sink 130 is fin-type and has a plurality of dissipation fins 136 to increase the dissipation area. In addition, the ceramic heat sink 130, which is lighter and conformed to the market demand and occupies lesser space, may be used in thin-type electronic products whose mechanical space is smaller.

Referring to FIG. 1A, a contact pad 124 disposed between the communication chip 120 and the ceramic heat sink 130 is made from a thermal conductive material such as silica gel which enhances the bonding between the communication chip 120 and the ceramic heat sink 130. The communication chip 120 may be realized by a communication chip which has wireless transmission and supports IEEE802.11a/b/g wireless network communication protocol, Bluetooth wireless communication or worldwide interoperability for microwave access (WIMAX).

Referring to FIG. 1A, the ceramic heat sink 130 is fixed on the communication chip 120 by using the elastic fastener 140. The elastic fastener 140 includes a first extension portion 142, a second extension portion 144 and a clamping portion 146. The first extension portion 142 extends to the first fixing member 112 along a first direction D1 from the first lateral side 132, and is engaged with the first fixing member 112 to generate a first fastening force F1. The second extension portion 144 extends to the second fixing member 114 along a second direction D2 from the second lateral side 134, and is engaged with the second fixing member 114 to generate a second fastening force F2.

In the present embodiment, the first fixing member 112 has a first through hole 112a, into which the terminal portion 142a of the first extension portion 142 is inserted for enabling the first fixing member 112 and the first extension portion 142 to generate a first fastening force F1. In addition, the second fixing member 114 has a second through hole 114a into which the terminal portion 144a of the second extension portion 144 is inserted for enabling the second fixing member 114 and the second extension portion 144 to generate a second fastening force F2. Preferably, the first extension portion 142 and the second extension portion 144 are parallel to the first lateral side 132 and the second lateral side 134 respectively, and extend for an equal length in opposite directions such that the magnitude of the first fastening force F1 is substantially equal to that of the second fastening force F2.

In addition, the clamping portion 146 is connected between the first extension portion 142 and the second extension portion 144, the clamping portion 146 contacts the ceramic heat sink 130 and applies a force on the ceramic heat sink 130 to tightly press the ceramic heat sink 130 on the communication chip 120. To summarize, the electronic device of the present embodiment uses the assembly of the elastic fastener 140, the first fixing member 112 and the second fixing member 114 as a clamping fastener for fixing the ceramic heat sink 130 on the communication chip 120. Thus, the heat sink is fixed on the chip and will not come off due to the deteriorated viscosity of the conventional gel which occurs after a period of use.

The clamping portion 146 passes through the center of the ceramic heat sink 130, and the two ends of the clamping portion 146 respectively connect the first extension portion 142 and the second extension portion 144. The first fastening force F1 and the second fastening force F2 applied on the two ends of the clamping portion 146 make the clamping portion 146 uniformly applies a force on the ceramic heat sink 130 to increase the contact area between the ceramic heat sink 130 and the communication chip 120.

In the present embodiment, the elastic fastener 140 is an elastic bendable metal wire made from stainless steel, for example. The metal wire is easy to process and is simple to assemble without using screws. Also, the diameters of the through holes of the first and the second fixing members 112 and 114 which are engaged with the elastic fastener 140 are small, and the ceramic heat sink 130 can be fixed without using any large-size fasteners or screws, so that the wires of the circuit board 110 are less affected.

The design of using the elastic fastener 140 to fix the ceramic heat sink 130 on the circuit board 110 provides a fastening force, which increases the dissipation efficiency of the ceramic heat sink 130 and prevents the ceramic heat sink 130 from peeling off. The magnitude of the fastening force may be calculated in advance and controlled to be not greater than the crushing stress of the ceramic heat sink 130 or the package stress bearable to the communication chip 120. Furthermore, the positions of the first fixing member 112 and the second fixing member 114 match up with the positions of the wires of the circuit board 110 in the optimization of the design.

According to the electronic device using a fastener for fixing disclosed in the above embodiments of the invention, the assembly of the elastic fastener, the first fixing member and the second fixing member increases the fastening force, which enlarges the contact area between the ceramic heat sink and the communication chip. Furthermore, the elements can be assembled without using screws, not only providing convenience in use but also shortening assembly time.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An electronic device using a fastener for fixing, comprising:
a circuit board having a first fixing member and a second fixing member disposed thereon;
a communication chip disposed on the circuit board;
a ceramic heat sink disposed on the communication chip, wherein the ceramic heat sink has a first lateral side and a second lateral side which are parallel and opposite to each other; and
an elastic fastener, comprising:
a first extension portion extending to the first fixing member from the first lateral side along a first direction and being engaged with the first fixing member to generate a first fastening force;
a second extension portion extending to the second fixing member from the second lateral side along a second direction and being engaged with the second fixing member to generate a second fastening force; and
a clamping portion connected between the first extension portion and the second extension portion, wherein the clamping portion contacts and applies a force on the ceramic heat sink to tightly press the ceramic heat sink on the communication chip.

2. The electronic device according to claim 1, wherein the first direction is opposite to the second direction.

3. The electronic device according to claim 1, wherein the magnitude of the first fastening force is equal to that of the second fastening force.

4. The electronic device according to claim 1, wherein the fastener is a metal wire.

5. The electronic device according to claim 4, wherein the metal wire is made from stainless steel.

6. The electronic device according to claim 1, further comprises a contact pad disposed between the communication chip and the ceramic heat sink.

7. The electronic device according to claim 6, wherein the contact pad is made from a thermal conductive material.

8. The electronic device according to claim 1, wherein the ceramic heat sink has a plurality of dissipation fins.
